(19) United States
(12) Patent Application Publication
(10) Pub. No.: US 2017/0345770 A1
(43) Pub. Date: Nov. 30, 2017

(54) METHOD FOR MAKING EMI SHIELDING LAYER ON A PACKAGE

(71) Applicant: UNIVERSAL SCIENTIFIC INDUSTRIAL (SHANGHAI) CO., LTD., Shanghai City (CN)

(72) Inventor: Pioneer CHIEN, CAOTUN TOWNSHIP, NANTOU COUNTY (TW)

(21) Appl. No.: 15/263,762

(22) Filed: Sep. 13, 2016

(30) Foreign Application Priority Data
May 25, 2016 (CN) 201610352028.0

(51) Int. Cl. H01L 23/552; H01L 21/3205; H01L 21/683; H01L 21/78

(52) U.S. Cl. CPC H01L 23/552; H01L 21/78; H01L 21/32051; H01L 21/6835; H01L 2221/68381

(57) ABSTRACT

A method for making EMI shielding layer of a package is disclosed to include the steps of: a) disposing a UV curable adhesive, which can be thermally released, on a surface of a package panel having solder pads to cover the solder pads; b) curing the UV curable adhesive; c) performing a singulating process to form the plurality of the packages disposed by the UV curable adhesive; d) forming an EMI shielding layer on the package; and e) thermally releasing the UV curable adhesive.

### BACKGROUND OF THE INVENTION

### 1. Field of the Invention

The present invention relates generally to EMI shielding technology, and more particularly, to a method for making an EMI shielding layer on a package, which prevents the EMI shielding layer from chipping or scratching.

### 2. Description of the Related Art

In a conventional SiP (System in package) module, the outer surface of the package is usually coated with an EMI shielding layer for shielding electromagnetic noises. However, in the conventional process of making EMI shielding layer, due to the requirement of production capacity, multi-strip or multi-panel designs are usually adapted. Therefore, adjacent packages may be connected to each other by the EMI shielding layers, so that an external force should be applied to separate each of the connected packages. When separating the packages, a part of the EMI shielding layer may be peeled off, or burrs and chips may be produced and adhered to the EMI shielding layer or the package, resulting in poor package appearance and shorting between the EMI shielding layer and the solder pads. Therefore, it is desirable to provide a method for making EMI shielding layer on a package, which can avoid producing burrs and chips on the EMI shielding layer on the package.

### SUMMARY OF THE INVENTION

The present invention has been accomplished in view of the above-noted circumstances. It is an objective of the present invention to provide a method for making EMI shielding layer on a package which can avoid burrs and chips on the EMI shielding layer.

To achieve the above objective, a method for making EMI shielding layer on a package is provided in the present invention to have the following steps: step a): disposing a UV curable adhesive which can be thermally released on a surface of a package panel having a plurality of solder pads to cover the solder pads; step b): curing the UV curable adhesive; step c): performing a singulating process to form the plurality of the packages disposed by the EMI shielding layer from the package panel; step d) fox an EMI shielding layer on each of the packages; and step e) thermally releasing the UV curable adhesive.

Thus, when the UV curable adhesive thermally expands subject to heat, the UV curable adhesive will separate from the solder pads of the package and exert a force to the EMI shielding layer on lateral side surface of package and break the EMI shielding layer on the lateral side surface. The force exerted toward the EMI shielding layer is uniformly distributed and slowly generated, avoiding producing burrs and chips on the EMI shielding layer.

In one aspect, in the present invention the solder pads of each of the packages are adhered to and covered by a layer of UV curable adhesive beforehand, effectively preventing shorting between the EMI shielding layer and the solder pads and further preventing the dysfunction of the package.

In another aspect, in the present invention the step of thermal releasing the UV curable adhesive can be carried out by a high temperature liquid. It is convenient to operate and not easy to produce chips and burrs.

In another aspect, the step of thermal releasing the UV curable adhesive may be carried out by employing the characteristics of different specific weight between the package and the UV curable adhesive in the high temperature liquid, so that the separation of the package and the UV curable adhesive can be achieved. The abovementioned process is time-saving and not easy to scratch the EMI shielding layer.

In another aspect, in the present invention the EMI shielding layer can be formed by spray coating. The apparatuses needed in spray coating are low in price, not needed to put in a clean room. It also has advantages of the apparatuses occupying less space, low environmental requirement, and time-saving in the formation step. Thus, the fabrication cost can be effectively reduced.

Other and further benefits, advantages and features of the present invention will be understood by reference to the following specification in conjunction with the accompanying drawings, in which like reference characters denote like elements of structure.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a flow chart of the method in accordance with a preferred embodiment of the present invention;

FIG. 2A-20 illustrate different cross-sectional views of a package, which shows different steps of the method in accordance with the preferred embodiment of the present invention; and

FIG. 3 is a schematic top view of a package panel in accordance with the preferred embodiment of the present invention.

### DETAILED DESCRIPTION OF THE INVENTION

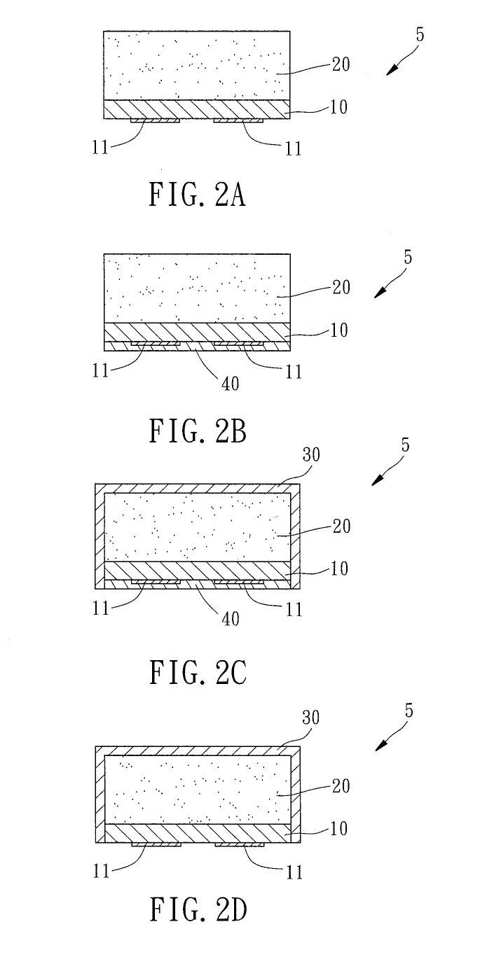

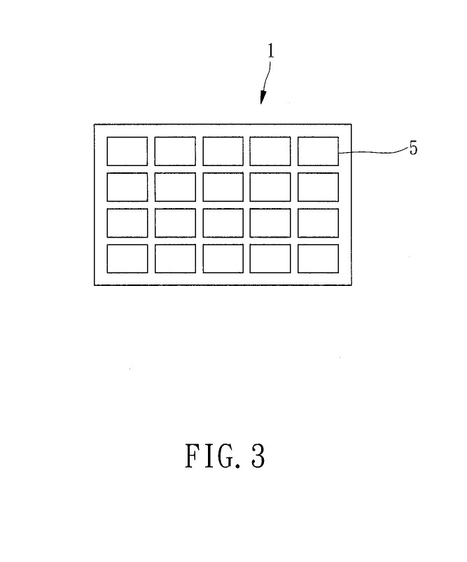

A preferred embodiment with the accompanying figures is provided to aid in the understanding of the present invention. A package panel 1 which is constituted by a plurality of packages 5 of SiP modules, shown in FIG. 3, is described below as an example according to the present invention. The SiP module may be, but not limited to a Fan out SiP or an Embedded SiP. Each structure of the package 5 of the package panel 1 is schematically shown in FIG. 2A, which is the cross-sectional view of the package 5. Each package 5 comprises a substrate 10 and a molding layer 20 located on a top of the substrate 10. A plurality of pads 11 are provided on a bottom surface of the substrate 10 for electric connection to other electronic devices outside the package 5. The steps for making EMI shielding layer 30 of a package 5 are described hereafter.

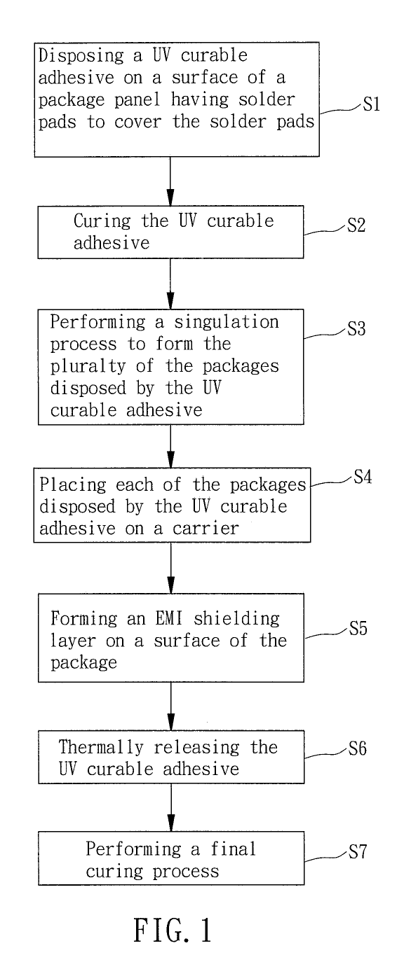

Refer to FIG. 1 first. Step S1: Disposing a ultraviolet (abbreviated to UV hereafter) curable adhesive 40, which can be thermally released, on a bottom surface of each substrate 10 of the package panel 1, in such a way that all of the bottom surface and the solder pads 11 are adhered and covered by the UV curable adhesive 40 (as shown in FIG. 2B). In the present embodiment, the bottom surface refers to a surface of the substrate 10 having the solder pads 11. The UV curable adhesive 40 is selected from the product from VALTRON® Company with the product model of AD4500. The UV curable adhesive 40 can cure within seconds after UV light exposure. The UV curable adhesive 40 can be debonded and thermally released from the substrate 10 by immersing the disposed substrate 10 in a high temperature liquid (hot water) in a temperature range from 90° C. to 95° C. or by placing the disposed substrate 10 in an oven in a temperature of 140° C.

After step S1, step S2 is performed. S2: curing the UV curable adhesive 40 by irradiating UV light toward the UV curable adhesive 40.

Then, perform step S3 of performing a singulation process to form the plurality of the packages 5 disposed by the UV curable adhesive 40 from the package panel 1.

After Step S3, perform step S4. S4: Using a pick and place machine to place and secure each of the packages 5 disposed by the UV curable adhesive 40 on a carrier (not shown in the figures).

Then, perform step S5. S5: Using a commonly used EMI shielding material to form an EMI shielding layer 30 (e. g. by spray coating) on an outer surface (e.g. a top surface and lateral sides surfaces of the package 5) of each package 5 which is disposed by the UV curable adhesive 40, and enabling electrically connection between the EMI shielding layer 30 and a grounding layer (not shown in the drawings) of each package 5 to shield the package 5 from exterior EMI radiation (as shown in FIG. 2C). The material of the EMI shielding layer 30 may be but not limited to metallic material or other composite material having electric conductor property. It is noted that when forming the EMI shielding layer 30 by spray coating, the EMI shielding layer 30 may be formed on a lateral side surface of the UV curable adhesive 40 or connected to another EMI shielding layer 30 of package 5 nearby.

Step S6: Thermal releasing the UV curable adhesive 40. In the present embodiment, each of the packages 5 having the EMI shielding layer 30 and the UV curable adhesive 40 is placed in a high temperature liquid to thermally release the UV curable adhesive 40. The referred high temperature liquid may be but not limited to a hot water (or different kind of liquid) in a temperature range from 90° C. to 95° C. or other liquid having temperature higher than 95° C. The UV curable adhesive 40 will separate from the solder pads 11 of the package 5 due to thermal expansion of the UV curable adhesive 40. During the thermal expansion of the UV curable adhesive 40, the EMI shielding layer 30 on the lateral side surface of the UV curable adhesive 40 will break along a bottom edge of the substrate 10. The UV curable adhesive 40 will separate easily and thoroughly from the package 5 because of the characteristics of different specific weights between the separated UV curable adhesive 40 and the separated package 5 in hot water. The adhesive-free package 5 is shown as FIG. 2D.

Step S7: Perform a final cure process to bake and dry the packages 5 (coated by EMI shielding layer 30), and finish the fabrication of the EMI shielding layer 30.

In the present embodiment, before forming the EMI shielding layer 30 on each package 5 in step S5, step S1 of disposing the UV curable adhesive 40 and covering the surface of the pads 11 is carried out beforehand, effectually preventing bridging and the shorting between the EMI shielding layer 30 and the solder pads 11.

Further, in step S6, the UV curable adhesive 40 thermal expands due to hot water. The expanding force exerted from the UV curable adhesive 40 toward the EMI shielding layer 30 is relatively evenly distributed and slowly generated, preventing the producing of chips and burrs on the EMI shielding layer 30 on the lateral side of the package 5.

What is claimed is:

1. A method for making EMI shielding layer on a package, comprising the steps of:
a) disposing a UV curable adhesive on a surface of a package panel having a plurality of solder pads to cover the solder pads; wherein the package panel comprises a plurality of the packages;
b) curing the UV curable adhesive;
c) Singulating the package panel to form the plurality of the packages disposed by the UV curable adhesive from the package panel;
d) forming an EMI shielding layer on each of the packages; and
e) thermal releasing the UV curable adhesive.

2. The method as claimed in claim 1, wherein the EMI shielding layer is formed by spray coating in step d).

3. The method as claimed in claim 1, further comprising a step f) of placing each of the packages disposed by the UV curable adhesive on a carrier between the step c) and the step d).

4. The method as claimed in claim 1, wherein each of the packages disposed by the UV curable adhesive is placed in a high temperature liquid to thermally release the UV curable adhesive in step e).

5. The method as claimed in claim 4, wherein each of the packages disposed by the UV curable adhesive is placed in water in a temperature of 90 to 95° C. in step e).

6. The method as claimed in claim 1, further comprising a step g) of baking and drying the packages.

7. The method as claimed in claim 2, wherein each of the packages disposed by the UV curable adhesive is placed in a high temperature liquid to thermally release the UV curable adhesive in step e).

8. The method as claimed in claim 2, further comprising a step g) of baking and drying the packages coated by the EMI shielding layer.

9. A method for making an EMI shielding layer on a package, comprising the steps of:
a) disposing a UV curable adhesive on a surface of a package panel having solder pads to cover the solder pads; wherein the package panel comprises a plurality of the packages;
b) curing the UV curable adhesive;
c) Singulating the package panel to form the plurality of the packages disposed by the UV curable adhesive from the package panel;
d) placing each of the packages disposed by the UV adhesive on a carrier;
e) forming an EMI shielding layer on each of the packages by spray coating; and
f) placing each of the packages having the UV curable adhesive and the EMI shielding layer in a high temperature liquid to thermally release the UV curable adhesive.

10. The method as claimed in claim 9, wherein each of the packages having the UV curable adhesive and the EMI shielding layer is placed in water in the step f).

11. The method as claimed in claim 10, wherein in the step f) each of the packages having the UV curable adhesive and the EMI shielding layer is placed in water in a temperature range from 90 to 95° C.

12. The method as claimed in claim 9, after the step f), further comprising a step g) of backing and drying of the packages.
